(19) United States
(12) Patent Application Publication
(10) Pub. No.: US 2021/0225619 A1
(43) Pub. Date: Jul. 22, 2021

(54) ELECTROSTATIC CHUCK

(71) Applicants: HOKURIKU SEIKEI INDUSTRIAL CO., LTD., Ishikawa (JP); ALIONTEK CORPORATION, Yamagata (JP)

(72) Inventors: Tomohisa SUZUKI, Ishikawa (JP); Michito MIYAHARA, Fukuoka (JP); Masaru SASAKI, Ishikawa (JP)

(73) Assignees: HOKURIKU SEIKEI INDUSTRIAL CO., LTD., Ishikawa (JP); ALIONTEK CORPORATION, Yamagata (JP)

(21) Appl. No.: 17/056,558

(22) PCT Filed: Jun. 26, 2019
(86) PCT No.: PCT/JP2019/025413

§ 371 Date: Nov. 18, 2020

(30) Foreign Application Priority Data
Jun. 29, 2018 (JP) 2018-125025

(51) Int. Cl. H01J 37/32; H02N 13/00

(52) U.S. Cl. CPC H01J 37/32724; H02N 13/00; H01J 2237/334; H01J 2237/2007; H01J 2237/0206; H01J 2237/002

(57) ABSTRACT

An electrostatic chuck can be manufactured at low cost and can securely prevent arcing even if the main body of the electrostatic chuck is thin. This electrostatic chuck is provided with an electrostatic chuck main body, an arcing prevention member, and a metal base member. The electrostatic chuck main body and the metal base member are provided with a plurality of vertical cooling gas holes. The arcing prevention member includes: a ceramic plate-shaped body through which a plurality of fine holes 20-100 μm in diameter pass; and an exterior member that secures the ceramic plate-shaped body and is disposed in an upper part of the vertical cooling gas holes. The ceramic plate-shaped body is thicker than the electrostatic chuck main body.

### TECHNICAL FIELD

The present invention relates to an electrostatic chuck for holding a substrate such as a wafer.

### BACKGROUND ART

Heretofore, an electrostatic chuck has been provided with a plurality of discharge passages for discharging cooling gas such as helium, at respective positions, so as to supply the cooling gas around a wafer or the like.

Further, a metal base member has been disposed in contact with a lower surface of a chuck body of the electrostatic chuck, so as to directly cool the chuck body.

The electrostatic chuck is used to allow a wafer to be processed by a plasma etching process or the like, while being placed on the chuck body. In recent years, the progress of plasma densification gives rise to a need for higher cooling efficiency of a wafer, and the thickness of the chuck body tends to be reduced from about 3 mm to 1.5 mm or less, so as to strengthen a wafer holding force and allow the holding force to be released within a short time of period.

However, when the chuck body is thinned, an abnormal electrical discharge (arcing) arises in the vicinity of the discharge passages for discharging cooling gas or the like, thereby leading to a problem that the generation of particles, damage to a wafer under processing, or breakage of the chuck body, is more likely to occur.

Further, recently, with a view to maintaining etching performance, cleaning of the inside of a plasma processing apparatus tends to be more frequently performed. Thus, although a dummy wafer is conventionally placed on the chuck body during each cleaning, the number of cases in which the cleaning was performed without the placement of the dummy wafer is increasing so as to improve productivity.

In such cases, the cleaning is performed in a situation where high-frequency electric power is applied to generate plasma under the condition that cleaning treatment gas such as oxygen gas is supplied to the inside of the plasma processing apparatus. This leads to a problem that arcing is more likely to arise in the vicinity of the cooling gas discharge passages.

As a technique for solving the problem arising from thinning of the chuck body, in Patent Document 1 (JP 5331519B), there is described an electrostatic chuck (11) comprising: a cooling member (1) having a gas supply hole (1a); a chuck body (2); and an anti-arcing member (13), as shown in FIG. 7, wherein: the cooling member has a primary spot-facing portion (1b) provided around the opening of the gas supply hole (1a) to have a diameter greater than that of the gas supply hole (1a); the anti-arcing member (13) is embedded in the primary spot-facing portion (1b), wherein the anti-arcing member (13) has a gas flow passage (13a) communicating with the gas supply hole (1a), and a secondary spot-facing portion (13b) provided in a central region thereof; and the chuck body (2) has a thin hole (2a) communicating with the gas supply hole (1a) via the secondary spot-facing portion (13b) and the gas flow passage (13a), whereby plasma is less likely to be generated within the gas supply hole (1a) (see, particularly, FIG. 2 and paragraphs [0008], [0034] and [0035] of Patent Document 1).

In Patent Document 2 (JP 6263484B), there is described an electrostatic chuck aimed at prevention of arcing, improvement in adhesion between a first molded body and a protective layer, prevention of contamination of a substrate, and the like.

As shown in FIG. 8, the electrostatic chuck described in the Patent Document 2 comprises a conductive substrate (1), an insulating molded body (2), and a protective layer (4) covering respective upper end surfaces of the substrate (1) and the molded body (2), wherein the substrate (1) is formed with a communication hole (10) having a stepped portion (11), and the molded body (2) is press-fitted into the communication hole (10).

The molded body (2) is composed of a first molded body (21) and a second molded body (22). The first molded body (21) has an outer stepped portion (211) provided on the side of an outer surface thereof at a position corresponding to the stepped portion (11) of the substrate (1), and an inner stepped portion (212) provided on the side of an inner surface thereof. The second molded body (22) has an outer stepped portion (222) provided on the side of an outer surface thereof at a position corresponding to the inner stepped portion (212) of the first molded body (21), and a hollow portion (20) provided in a central region thereof, and the protective layer (4) is provided with a through-hole (40) communicating with the hollow portion (20).

The hollow portion (20) and the through-hole (40) make up a gas pathway of the electrostatic chuck (see, particularly, FIG. 1, and paragraphs [0019] to [0021] and [0026] to [0030] of the Patent Document 2).

### CITATION LIST

### Parent Document

Patent Document 1: JP 5331519B
Patent Document 2: JP 6263484B

### SUMMARY OF INVENTION

### Technical Problem

However, the electrostatic chuck described in the Patent Document 1 requires embedding the anti-arcing member (13) into the primary spot-facing portion (1b) provided around the gas supply hole (1a), and providing the thin hole (2a) and the gas flow passage (13a), respectively, in the chuck body (2) and the anti-arcing member (13).

Further, the electrostatic chuck described in the Patent Document 2 requires: press-fitting the molded body (2) into the communication hole (10) having the stepped portion (11) or the like; composing the molded body (2) of the first molded body (21) and the second molded body (22); and providing the hollow portion (20) and the through-hole (40), respectively, in the second molded body (22) and the protective layer (4). Here, the configuration of a chuck body of the electrostatic chuck described in the Patent Document 2 is unknowable.

Therefore, due to the necessity for formation of the gas supply hole (1a) or the communication hole (10), embedding of the anti-arcing member (13), the formation of the small-diameter thin hole (2a) and the gas flow passage (13a), or the hollow portion (20) and the through-hole (40), and others, these electrostatic chucks involve the problem of a rise in manufacturing cost.

It is an object of the present invention to solve the above problem and provide, at low cost, an electrostatic chuck which is capable of reliably preventing arcing, even in a situation where a chuck body of the electrostatic chuck is relatively thin, and the inside of a plasma processing apparatus is subjected to cleaning without placing a dummy wafer on the chuck body.

### Solution to Technical Problem

According to a first aspect of the present invention, there is provided an electrostatic chuck comprising: a chuck body having a wafer placement surface which is disposed in a plasma processing apparatus and on which a wafer is electrostatically held; an anti-arcing member; and a metal base member supporting the chuck body, wherein: the chuck body and the metal base member are provided with a cooling gas hole, and a plurality of cooling gas-distributing vertical holes each connected to the cooling gas hole and penetrating therethrough to reach the wafer placement surface; and the anti-arcing member is comprised of a ceramic body through which a plurality of thin holes each having a diameter of 20 to 100 μm and serving as a cooling gas discharge passage penetrate, and disposed in an upper part of each of the plurality of cooling gas-distributing vertical holes, wherein the ceramic body has a thickness greater than that of the chuck body, as recited in the appended claim 1.

Preferably, in the electrostatic chuck according to the first aspect of the present invention, the anti-arcing member has a columnar body, wherein the plurality of thin holes are arranged parallel with respect to a central axis of the columnar body, as recited in the appended claim 2.

According to a second aspect of the present invention, there is provided an electrostatic chuck comprising: a chuck body having a wafer placement surface which is disposed in a plasma processing apparatus and on which a wafer is electrostatically held; an anti-arcing member; and a metal base member supporting the chuck body, wherein: the chuck body and the metal base member are provided with a cooling gas hole, and a plurality of cooling gas-distributing vertical holes each connected to the cooling gas hole and penetrating therethrough to reach the wafer placement surface; and the anti-arcing member is comprised of a ceramic body through which a plurality of thin holes each having a diameter of 20 to 100 μm and serving as a cooling gas discharge passage penetrate, and an exterior member to which the ceramic body is fixed, and disposed in an upper part of each of the plurality of cooling gas-distributing vertical holes, wherein the ceramic body is separated into an inflow-side body fixed to a cooling-gas inflow side of the exterior member, and a discharge-side body fixed to a cooling-gas discharge side of the exterior member, as recited in the appended claim 3.

Preferably, in the electrostatic chuck according to the second aspect of the present invention, the anti-arcing member has a columnar body, wherein the plurality of thin holes each penetrating through the inflow-side body are arranged parallel and at a first distance with respect to the central axis of the columnar body, and the plurality of thin holes each penetrating through the discharge-side body are arranged parallel and at a second distance with respect to the central axis of the columnar body, wherein the first distance and the second distance are different distances, as recited in the appended claim 4.

Preferably, in the electrostatic chuck according to the second aspect of the present invention, the inflow-side body and the discharge-side body are arranged with a gap of 1.1 mm or less therebetween, as recited in the appended claim 5.

Preferably, in the electrostatic chuck according to the second aspect of the present invention, the exterior member is made of a ceramic material, wherein the ceramic body is fixed to the exterior member by attaching means which is one selected from the group consisting of adhesive bonding, fitting engagement, and simultaneous sintering, as recited in the appended claim 6.

Preferably, in the electrostatic chuck according to the first or second aspect of the present invention, the ceramic body has a relative density of 95% or more, wherein a pore lying in a sintered microstructure of the ceramic body is formed as closed pores which are free from continuous mutual contact, and wherein the ceramic body has a material strength of 400 MPa in terms of bending strength, as recited in the appended claim 7.

### Effect of Invention

In the electrostatic chuck as recited in the appended claim 1, the anti-arcing member is comprised of a ceramic body through which a plurality of thin holes each having a diameter of 20 to 100 μm and serving as a cooling gas discharge passage penetrate, so that it is possible to prevent cooling gas from intensively blowing out toward a wafer, thereby suppressing deformation of the wafer due to the blowout of cooling gas.

Further, the thickness of the ceramic body is greater than that of the chuck body, so that it is possible to reliably prevent arcing even in a situation where the chuck body is relatively thin.

Further, the cooling gas discharge passage can be formed simply by disposing the anti-arcing member in the upper part of each of the cooling gas-distributing vertical holes, so that it is possible to manufacture the electrostatic chuck at low cost.

In the electrostatic chuck as recited in the appended claim 2, the anti-arcing member has a columnar body. Thus, in addition to the advantageous effects of the electrostatic chuck as recited in the appended claim 1, the electrostatic chuck as recited in the appended claim 2 provides an advantage of allowing each of the plurality of cooling gas-distributing vertical holes provided in the chuck body and the metal base member to be formed as a straight hole.

Further, the plurality of thin holes are arranged parallel with respect to a central axis of the columnar body, so that it is possible to easily fabricate the plurality of thin holes.

Thus, the electrostatic chuck can be manufactured at lower cost.

In the electrostatic chuck as recited in the appended claim 3, the anti-arcing member is comprised of a ceramic body through which a plurality of thin holes each having a diameter of 20 to 100 μm and serving as a cooling gas discharge passage penetrate, and an exterior member to which the ceramic body is fixed, wherein the ceramic body is separated into an inflow-side body fixed to a cooling-gas inflow side of the exterior member, and a discharge-side body fixed to a cooling-gas discharge side of the exterior member, so that it is possible to provide an electrostatic chuck capable of suppressing deformation of a wafer due to blowout of cooling gas, and reliably prevent arcing, even if the anti-arcing member is thinned.

Further, the cooling gas discharge passage can be formed simply by disposing the anti-arcing member in the upper part of each of the cooling gas-distributing vertical holes, so that it is possible to manufacture the electrostatic chuck at low cost.

In the electrostatic chuck as recited in the appended claim 4, the anti-arcing member has a columnar body. Thus, in addition to the advantageous effects of the electrostatic chuck as recited in the appended claim 3, the electrostatic chuck as recited in the appended claim 4 provides an advantage of allowing each of the plurality of cooling gas-distributing vertical holes provided in the chuck body and the metal base member to be formed as a straight vertical hole.

Further, the plurality of thin holes each penetrating through the inflow-side body are arranged parallel and at a first distance with respect to the central axis of the columnar body, and the plurality of thin holes each penetrating through the discharge-side body are arranged parallel and at a second distance with respect to the central axis of the columnar body, so that it is possible to easily fabricate the plurality of thin holes.

Thus, the electrostatic chuck can be manufactured at lower cost.

Further, the first distance and the second distance are different distances, so that it is possible to provide an electrostatic chuck capable of more reliably preventing arcing.

In the electrostatic chuck as recited in the appended claim 5, the inflow-side body and the discharge-side body are arranged with a gap of 1.1 mm or less therebetween. Thus, in addition to the advantageous effects of the electrostatic chuck as recited in the appended claim 3 or 4, the electrostatic chuck as recited in the appended claim 5 provides an advantage of being able to reliably prevent arcing.

In the electrostatic chuck as recited in the appended claim 6, the exterior member is made of a ceramic material, wherein the ceramic body is fixed to the exterior member by attaching means which is one selected from the group consisting of adhesive bonding, fitting engagement, and simultaneous sintering. Thus, in addition to the advantageous effects of the electrostatic chuck as recited in any one of the appended claims 3 to 5, the electrostatic chuck as recited in the appended claim 6 provides an advantage of allowing the anti-arcing member to be easily assembled.

In the electrostatic chuck as recited in the appended claim 7, the ceramic body has a relative density of 95% or more, wherein a pore lying in a sintered microstructure of the ceramic body is formed as closed pores which are free from continuous mutual contact, and wherein the ceramic body has a material strength of 400 MPa in terms of bending strength. Thus, in addition to the advantageous effects of the electrostatic chuck as recited in any one of the appended claims 1 to 6, the electrostatic chuck as recited in the appended claim 7 provides advantages of being able to: allow each of the thin holes to have a dense inner surface so as to attain low gas flow resistance; make chipping less likely to occur during handling; and allow the anti-arcing member to exhibit strong plasma resistance.

### BRIEF DESCRIPTION OF DRAWINGS

FIG. 1 is a sectional view of an electrostatic chuck according to a first embodiment of the present invention.

FIG. 2 is sectional view of an upper part of a cooling gas-distribution vertical hole and the vicinity thereof in the first embodiment.

FIGS. 3A and 3B are, respectively, a sectional view and a top plan view of an anti-arcing member in the first embodiment.

FIG. 4 is sectional view of an upper part of a cooling gas-distribution vertical hole and the vicinity thereof in an electrostatic chuck according to a second embodiment of the present invention.

FIGS. 5A, 5B and 5C are, respectively, a sectional view, a top plan view and a bottom view of an anti-arcing member in the second embodiment.

FIGS. 6A and 6B are, respectively, a sectional view and a top plan view of an anti-arcing member in an electrostatic chuck according to a third embodiment of the present invention.

FIG. 7 is a sectional view of an electrostatic chuck described in the Patent Document 1.

FIG. 8 is a sectional view of an electrostatic chuck described in the Patent Document 2.

### DESCRIPTION OF EMBODIMENTS

The present invention will now be described based on preferred embodiments thereof.

### First Embodiment

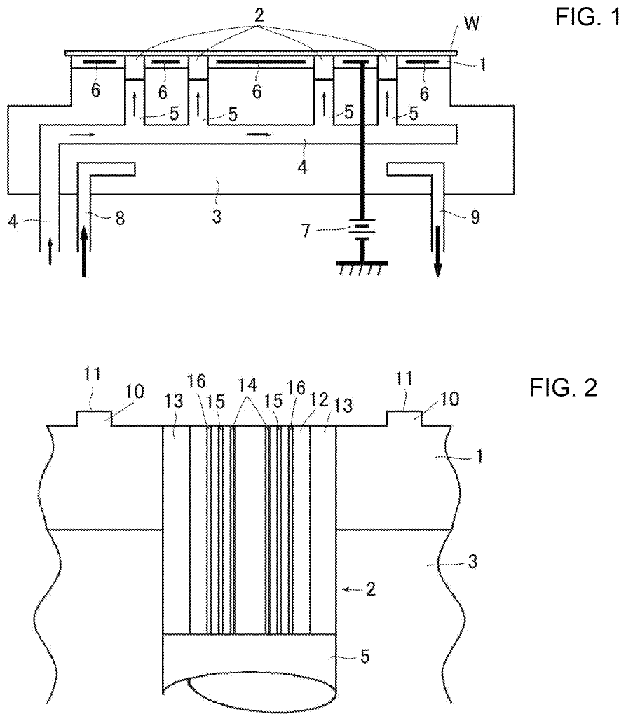

An electrostatic chuck according to a first embodiment of the present invention illustrated in FIG. 1 comprises: a chuck body 1 having a wafer placement surface on which a wafer W is electrostatically held and having a thickness of about 1 mm; an anti-arcing member 2 having a thickness of about 2 mm; and a metal base member 3 supporting the chuck body 1.

The metal base member 3 is internally provided with a cooling gas hole 4 extending approximately horizontally, and the chuck body 1 and the metal base member 3 are provided with a plurality of cooling gas-distributing vertical holes 5 each connected to the cooling gas hole 4 and approximately vertically penetrating therethrough to reach the wafer placement surface.

Here, each of the cooling gas-distributing vertical holes 5 has a circular shape in horizontal section, and openings of the cooling gas-distributing vertical holes 5 on the wafer placement surface are arranged at approximately even intervals.

An internal electrode 6 is buried in the chuck body 1, and electrically connected to a high-voltage DC power source 7 to allow the wafer W to be electrostatically held on the wafer placement surface.

The metal base member 3 is also provided with a cooling water supply pipe 8 and a cooling water outlet pipe 9, whereby the metal base member 3 can be forcedly cooled, so that the chuck body 1 is cooled from the side of a lower surface thereof, and then the wafer W is cooled from the side of a lower surface thereof.

FIG. 2 is sectional view of an upper part of one of the cooling gas-distribution vertical holes 5 and the vicinity thereof in the first embodiment.

As shown in FIG. 2, a plurality of small protrusions 10 are formed on an upper surface of the chuck body 1, and upper surfaces of the small protrusions 10 serve as the wafer placement surface 11.

The anti-arcing member 2 is formed in a circular columnar shape, and attached to an upper part of the cooling gas-distribution vertical hole 5, wherein an outer surface of the anti-arcing member 2 is attached firmly to respective inner surfaces of the chuck body 1 and the metal base member 3 defining the upper part of the cooling gas-distribution vertical hole 5.

The anti-arcing member 2 is comprised of a columnar-shaped ceramic body 12 having a diameter of 1.2 mm, and a cylindrical sleeve-shaped exterior member 13 having an outer diameter of 1.8 mm and an inner diameter of 1.2 mm. The ceramic body 12 is fitted into the exterior member 13, such that an outer surface of the ceramic body 12 is attached firmly and fixed to an inner surface of the exterior member 13.

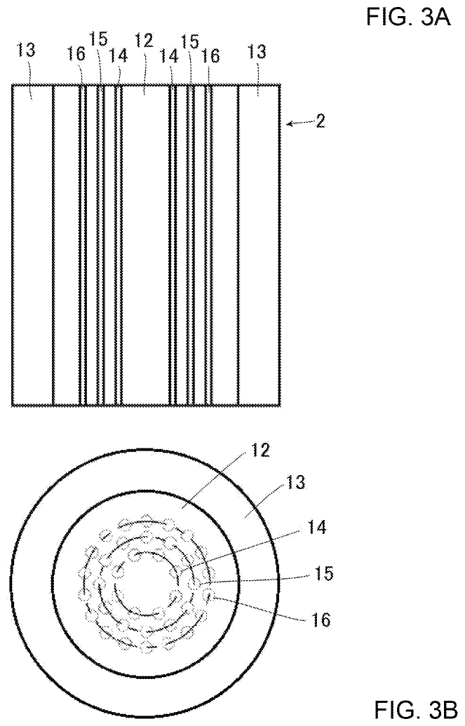

FIGS. 3A and 3B are, respectively, a sectional view and a top plan view of the anti-arcing member 2 in the first embodiment.

As shown in FIG. 3B, the ceramic body 12 is formed with: eight thin holes 14 arranged parallel and at a distance of 0.2 mm with respect to a central axis of the ceramic body 12; twelve thin holes 15 arranged parallel and at a distance of 0.3 mm with respect to the central axis; and eighteen thin holes 16 arranged parallel and at a distance of 0.4 mm with respect to the central axis.

Here, each of the thin holes 14, 15, 16 has a diameter of 50 μm.

The thin holes 14, 15, 16 formed in the ceramic body 12 can be fabricated by an apparatus and a method described in JP 5119353B which is a patented invention of the present applicant and a co-applicant.

Specifically, the thin holes is formed through a method comprising: a step (1) of preparing a kneaded material by mixing a raw material powder of a ceramic material, a binder for extrusion molding, and water; a step (2) of inserting a plurality of filaments each having a cavity in a longitudinal direction thereof and made of a synthetic resin, a carbon material or a metal material, across an extrusion molding die to which a filament guide and an orifice are assembled; a step (3) of supplying the kneaded material into the extrusion molding die while the filaments are pulled in a tensioned state, and extruding the kneaded material and the filaments from the orifice to obtain an extrusion-molded body containing the filaments in an axial direction thereof; a step (4) of cutting the extrusion-molded body into a given length to form a green body, or a step (4′) of cutting the extrusion-molded body into a given length, and pulling and removing the filaments the cut body to form a green body for a nozzle material; and a step (5) of, during burning of the green body obtained in the step (4) to attain degreasing and sintering, vaporizing and burning out the filaments made of a synthetic resin or a carbon material to form a plurality of straight through-holes each parallel to an axis of the resulting sintered body, or a step (5′) of subjecting the green body obtained in the step (4′) to degreasing and sintering to form a plurality of through-holes each parallel to an axis of the resulting sintered body (see, specifically, paragraphs [0022], [0023], [0031] to [0035] and [0054], and FIGS. 1, 2 and 6 of the above patent).

### Second Embodiment

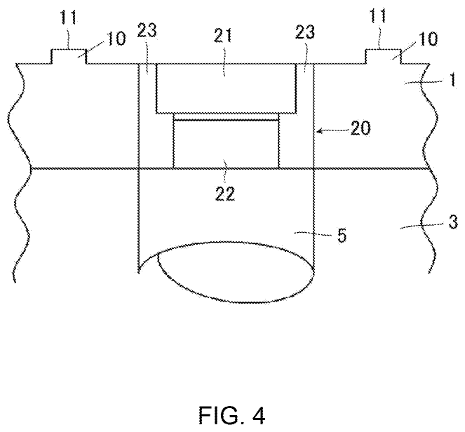

FIG. 4 is sectional view of an upper part of one of a plurality of cooling gas-distribution vertical holes 5 and the vicinity thereof in an electrostatic chuck according to a second embodiment of the present invention.

Except for the configuration of the upper part of the cooling gas-distribution vertical hole 5 and the vicinity thereof illustrated in FIG. 4, the electrostatic chuck according to the second embodiment has the same configuration as that of the electrostatic chuck according to the first embodiment illustrated in FIG. 1.

Therefore, in the following description, the same element or component as that in the first embodiment is assigned with the same reference sign as that used in the first embodiment, and description thereof will be omitted.

As shown in FIG. 4, a circular columnar-shaped anti-arcing member 20 is attached to the upper part of the cooling gas-distributing vertical hole 5, wherein an outer surface of the anti-arcing member 20 is attached firmly to the inner surfaces of the chuck body 1 defining the upper part of the cooling gas-distribution vertical hole 5.

The anti-arcing member 20 is composed of: a columnar-shaped ceramic discharge-side body 21 having a diameter of 1.6 mm and a thickness of 0.45 mm; a columnar-shaped ceramic inflow-side body 22 having a diameter of 1.2 mm and a thickness of 0.45 mm; and a cylindrical sleeve-shaped exterior member 23 having an outer diameter of 1.8 mm and a stepped portion provided on the side of an inner surface thereof. The ceramic discharge-side body 21 and the ceramic inflow-side body 22 are fitted, respectively, into an upper region and a lower region of the inner surface of the exterior member 23, and respective outer surfaces of the ceramic discharge-side body 21 and the ceramic inflow-side body 22 are attached firmly and fixed to the inner surface of the exterior member 23.

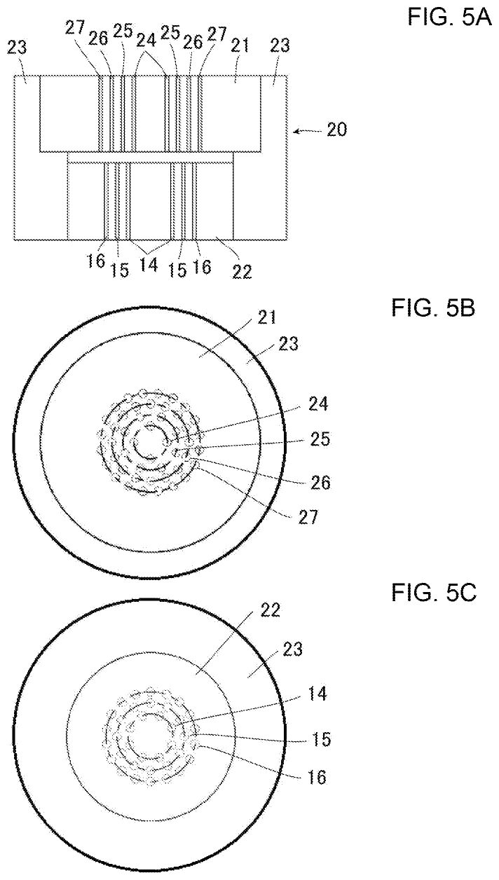

FIGS. 5A, 5B and 5C are, respectively, a sectional view, a top plan view and a bottom view of an anti-arcing member 20 in the second embodiment.

As shown in FIGS. 5B and 5C, the ceramic discharge-side body 21 is formed with: four thin holes 24 arranged parallel and at a distance of 0.15 mm with respect to a central axis of the ceramic discharge-side body 21; eight thin holes 25 arranged parallel and at a distance of 0.25 mm with respect to the central axis; sixteen thin holes 26 arranged parallel and at a distance of 0.35 mm with respect to the central axis; and twenty thin holes 27 arranged parallel and at a distance of 0.45 mm with respect to the central axis.

Further, the ceramic inflow-side body 22 is formed with: eight thin holes 14 arranged parallel and at a distance of 0.2 mm with respect to a central axis of the ceramic inflow-side body 22; twelve thin holes 15 arranged parallel and at a distance of 0.3 mm with respect to the central axis; and eighteen thin holes 16 arranged parallel and at a distance of 0.4 mm with respect to the central axis, in a manner similar to the ceramic body 12 in the first embodiment.

Here, each of the thin holes 14, 15, 16, 24, 25, 26, 27 has a diameter of 30 μm.

The thin holes 24, 25, 26, 27 formed in the ceramic discharge-side body 21 and the thin holes 14, 15, 16 formed in the ceramic inflow-side body 22 can be fabricated by the apparatus and the method described in the JP 5119353B which is a patented invention of the present applicant and a co-applicant, as with the first embodiment.

The ceramic discharge-side body 21 and the ceramic inflow-side body 22 are arranged with a gap of 0.1 mm therebetween, so that the gas is diffused therein. Further, the thin holes 14, 15, 16, 24, 25, 26, 27 are arranged at different distances with respect to the central axis. These make it possible to reliably prevent arcing even if the body is thinned,

### Third Embodiment

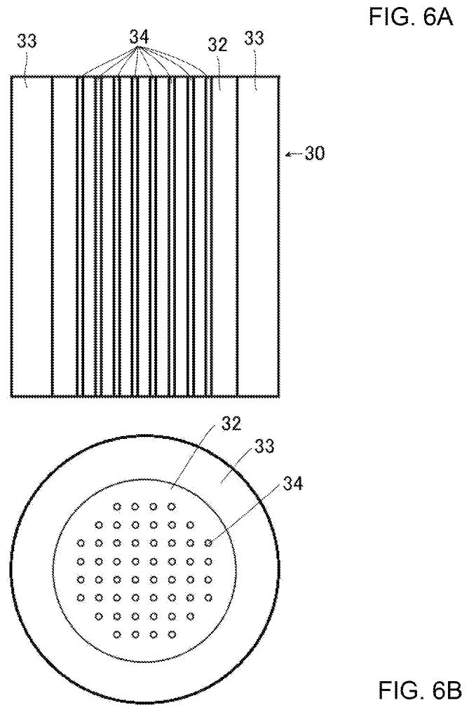

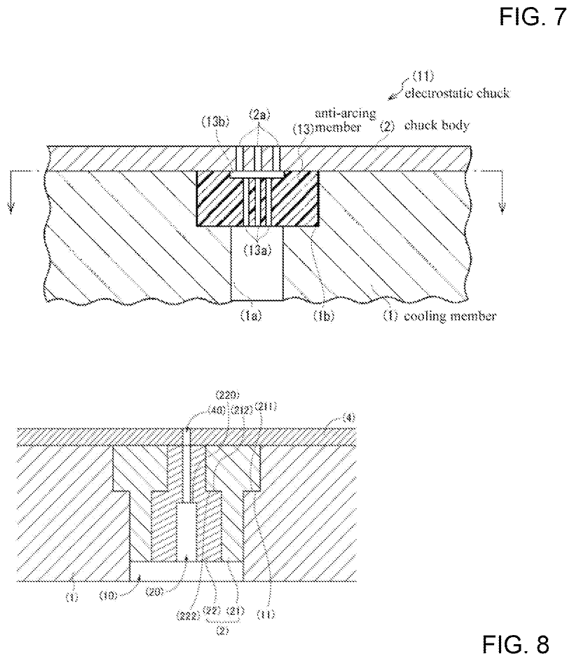

FIGS. 6A and 6B are, respectively, a sectional view and a top plan view of an anti-arcing member 30 in an electrostatic chuck according to a third embodiment of the present invention.

Except for the configuration of the anti-arcing member 30 illustrated in FIGS. 6A and 6B, the electrostatic chuck according to the third embodiment has the same configuration as that of the electrostatic chuck according to the first embodiment.

Therefore, in the following description, the same element or component as that in the first embodiment is assigned with the same reference sign as that used in the first embodiment, and description thereof will be omitted.

The anti-arcing member 30 is comprised of a circular columnar-shaped ceramic body 32 having a diameter of 1.2 mm, and a cylindrical sleeve-shaped exterior member 33 having an outer diameter of 1.8 mm and an inner diameter of 1.2 mm. The ceramic body 32 is fitted into the exterior member 33, such that an outer surface of the ceramic body 32 is attached firmly and fixed to an inner surface of the exterior member 33.

As shown in FIGS. 6A and 6B, in the ceramic body 32, a line of four thin holes 34, a line of six thin holes 34, a line of eight thin holes 34, a line of eight thin holes 34, a line of eight thin holes 34, a line of eight thin holes 34, a line of six thin holes 34, and a line of four thin holes 34, are arranged parallel with respect to a central axis of the ceramic body 32, wherein a distance between adjacent two of the lines of thin holes 34 is 0.3 mm.

Here, each of the fifty-two thin holes 34 has a diameter of 50 μm.

The thin holes 34 formed in the ceramic body 32 can be fabricated by the apparatus and the method described in the JP 5119353B which is a patented invention of the present applicant and a co-applicant, as with the first embodiment.

Some modifications of the above embodiments will be enumerated as follows.

(1) In the first and third embodiments, each of the anti-arcing members 2, 30 is formed in a circular columnar shape, and the thickness thereof is set to be greater than that of the chuck body 1. However, the shape is not limited to the circular columnar shape, but may be a rectangular columnar shape or an elliptic columnar shape. Further, with regard to thickness, the thickness of only the ceramic body 12 or 32 to be fixed to the exterior member 13 or 33 may be set to be greater than that of the chuck body 1.

(2) In the first to third embodiments, a material for the exterior members 13, 23, 33 is not specified. However, from a viewpoint of anti-arcing, they are preferably made of an insulating material, more preferably, a ceramic material.

(3) In the first to third embodiments, fixing between the ceramic body 12 and the exterior member 13 is performed by fitting engagement. Alternatively, the fixing may be performed by adhesive bonding. Further, in a case where the exterior member 13 is made of a ceramic material, the fixing may be performed by simultaneous sintering.

Further, in FIGS. 2, 3A and 3B of the first embodiment and FIGS. 6A and 6B of the third embodiment, the anti-arcing member 2 or 30 in which the ceramic body 12 or 32 is fixed to the exterior member 13 or 33 is attached to each of the cooling gas-distributing vertical holes 5. Alternatively, the ceramic body 12 or 32 may be formed to have a diameter equal to an outer diameter of the exterior member 13 or 33, and directly attached to each of the cooling gas-distributing vertical holes 5.

In this case, the fixing between the ceramic body 12 or 32 and the exterior member 13 or 33 can be omitted, so that it is possible to further reduce the manufacturing cost.

(4) In the first to third embodiments, sizes and arrangements of the ceramic bodies 12, 32, the ceramic discharge-side body 21, the ceramic inflow-side body 22, the exterior members 13, 23, 33 and the thin holes 14, 15, 16, 24, 25, 26, 27, 34 are specified. However, as long as a sufficient amount of cooling gas can be supplied, they may be appropriately set in consideration of the diameter and arrangement of the thin holes, wherein it is necessary to ensure a flow rate of 0.4 sccm per 1000 mm² as measured when a differential pressure is 1000 Pa.

Specifically, in the first and third embodiments, the thin hole may be provided in a number of 150 or more per 1000 mm², and, in the second embodiment, the thin hole (in the ceramic inflow-side body 22) may be provided in a number of 400 or more per 1000 mm².

From the viewpoint of anti-arcing, the diameter of the thin holes 14, 15, 16, 24, 25, 26, 27, 34 is preferably set in the range of 20 to 100 μm, more preferably 20 to 80 μm.

Further, an aspect ratio which is the ratio (L/D) of the length L to the diameter D of the thin hole is preferably set to 5 or more, more preferably 10 or more.

(5) In the first to third embodiments, all the thin holes 14, 15, 16, the thin holes 24, 25, 26, 27 and the thin holes 34 are arranged parallel with respect to the central axis. However, they do not necessarily have to be arranged parallel with respect to the central axis.

(6) In the first and third embodiments, in order to be adapted to a thin chuck body 1, the thickness of the ceramic body (2 or 30) is set to be greater than that of the chuck body 1. However, in a case where the chuck body 1 has a relatively large thickness of about 3 mm, the thickness of the ceramic body may be set to be less than that of the chuck body 1.

(7) In the second embodiment (FIGS. 4 and 5A to 5C), the two ceramic bodies (the ceramic discharge-side body 21 and the ceramic inflow-side body 22) are separately fixed. Alternatively, three or more ceramic bodies may be separately fixed.

(8) In the second embodiment, the ceramic discharge-side body 21 and the ceramic inflow-side body 22 are arranged with a gap of 0.1 mm therebetween. The magnitude of the gap may be appropriately changed.

Here, the gap may be set to 1.1 mm or less. Generally, the gap is selectively set in the range of 0.05 to 1 mm.

(9) In the second embodiment, the thickness of the anti-arcing member 20 is equal to that of the chuck body 1, and the outer surface of the anti-arcing member 20 is attached firmly to the inner surface of the chuck body 1. Alternatively, the thickness of the anti-arcing member 20 may be set to be less than or greater than that of the chuck body 1.

### LIST OF REFERENCE SIGNS

1: chuck body
2: anti-arcing member
3: metal base member
4: cooling gas hole
5: cooling gas-distributing vertical hole
6: internal electrode
7: high-voltage DC power supply
8: cooling water supply pipe
9: cooling water outlet pipe
10: small protrusion
11: wafer placement surface
12: ceramic body
13: exterior member
14 to 16: thin hole
20: anti-arcing member
21: ceramic discharge-side body
22: ceramic inflow-side body
23: exterior member
24 to 27: thin hole
30: anti-arcing member
32: ceramic body
33: exterior member
34: thin hole
D: diameter of thin hole
L: length of thin hole
W: wafer

1. An electrostatic chuck comprising: a chuck body having a wafer placement surface which is disposed in a plasma processing apparatus and on which a wafer is electrostatically held; an anti-arcing member; and a metal base member supporting the chuck body,
wherein:
the chuck body and the metal base member are provided with a cooling gas hole, and a plurality of cooling gas-distributing vertical holes each connected to the cooling gas hole and penetrating therethrough to reach the wafer placement surface; and
the anti-arcing member is comprised of a ceramic body through which a plurality of thin holes each having a diameter of 20 to 100 μm and serving as a cooling gas discharge passage penetrate, and disposed in an upper part of each of the plurality of cooling gas-distributing vertical holes, wherein the ceramic body has a thickness greater than that of the chuck body.

2. The electrostatic chuck as recited in claim 1, wherein the anti-arcing member has a columnar body, and wherein the plurality of thin holes are arranged parallel with respect to a central axis of the columnar body.

3. An electrostatic chuck comprising: a chuck body having a wafer placement surface which is disposed in a plasma processing apparatus and on which a wafer is electrostatically held; an anti-arcing member; and a metal base member supporting the chuck body,
wherein:
the chuck body and the metal base member are provided with a cooling gas hole, and a plurality of cooling gas-distributing vertical holes each connected to the cooling gas hole and penetrating therethrough to reach the wafer placement surface; and
the anti-arcing member is comprised of a ceramic body through which a plurality of thin holes each having a diameter of 20 to 100 μm and serving as a cooling gas discharge passage penetrate, and an exterior member to which the ceramic body is fixed, and disposed in an upper part of each of the plurality of cooling gas-distributing vertical holes, wherein the ceramic body is separated into an inflow-side body fixed to a cooling-gas inflow side of the exterior member, and a discharge-side body fixed to a cooling-gas discharge side of the exterior member.

4. The electrostatic chuck as recited in claim 3, wherein the anti-arcing member has a columnar body, and wherein the plurality of thin holes each penetrating through the inflow-side body are arranged parallel and at a first distance with respect to the central axis of the columnar body, and the plurality of thin holes each penetrating through the discharge-side body are arranged parallel and at a second distance with respect to the central axis of the columnar body, wherein the first distance and the second distance are different distances.

5. The electrostatic chuck as recited in claim 3, wherein the inflow-side body and the discharge-side body are arranged with a gap of 1.1 mm or less therebetween.

6. The electrostatic chuck as recited in claim 3, wherein the exterior member is made of a ceramic material, and wherein the ceramic body is fixed to the exterior member by attaching means which is one selected from the group consisting of adhesive bonding, fitting engagement, and simultaneous sintering.

7. The electrostatic chuck as recited in claim 1, wherein the ceramic body has a relative density of 95% or more, wherein a pore lying in a sintered microstructure of the ceramic body is formed as closed pores which are free from continuous mutual contact, and wherein the ceramic body has a material strength of 400 MPa in terms of bending strength.

8. The electrostatic chuck as recited in claim 3, wherein the ceramic body has a relative density of 95% or more, wherein a pore lying in a sintered microstructure of the ceramic body is formed as closed pores which are free from continuous mutual contact, and wherein the ceramic body has a material strength of 400 MPa in terms of bending strength.
